(19) United States
(12) Patent Application Publication
(10) Pub. No.: US 2026/0282264 A1
(43) Pub. Date: Sep. 17, 2026

(54) TRAY EJECT DETECTION

(71) Applicant: NVIDIA CORPORATION, Santa Clara, CA (US)

(72) Inventors: Lisa Yu, Saratoga, CA (US); Nick Whidden, San Jose, CA (US); Ken Misin, Santa Rosa, CA (US); Jeremy Baus, Raleigh, NC (US); Ryan Albright, Beaverton, OR (US); Ryan Wells, Raleigh, NC (US); James S. Fields, JR., Santa Fe, NM (US); Elad Mentovich, Tel Aviv (IL); Jimmy Daley, Santa Clara, CA (US)

(21) Appl. No.: 19/079,880

(22) Filed: Mar. 14, 2025

(51) Int. Cl. H05K 7/14; H05K 5/02

(52) U.S. Cl. CPC H05K 7/1492; H05K 5/023; H05K 7/1487; H05K 7/1489

(57) ABSTRACT

A server tray is provided that includes a sensing element and a controller circuit. The sensing element is configured to detect initiation of a power supply removal. The controller circuit is configured to initiate a controlled power down sequence for the server tray responsive to a defined eject state being detected by the sensing element.

### BACKGROUND

Datacenters often include a plurality of server racks that host server trays of computing resources (e.g., graphical processing units (GPUs), central processing units (CPUs), data processing units (DPUs), and/or the like) and resource orchestrators. Different server trays may have different requirements regarding power supply, connection with a server rack, connection with other server trays, and/or the like. For example, a server rack may transmit power from a power supply of the server rack to respective server trays of the server rack. However, conventional server trays are susceptible to data corruption and/or hardware damage when being disconnected from a power supply of a server rack. Therefore, a need exists for solutions that mitigate potential data corruption and/or hardware damage when disconnecting a server tray from a power supply.

### GENERAL DESCRIPTION

As artificial intelligence and/or machine learning use increases, the amount of information being processed by datacenters and communicated between large clusters of computing resources (e.g., graphical processing units (GPUs), central processing units (CPUs), data processing units (DPUs), and/or the like) is also increasing. The computing resources of datacenters are generally hosted by server trays mounted within server racks. In order to power the computing resources, a server tray receives electrical power from a busbar. For example, a server tray may include a busbar connector configured for interfacing with the busbar to receive electrical power therefrom. In use, the server tray may be locked into a server rack such that the busbar connector of the server tray remains connected with the electrical power supply and to ensure that one or more network connections remain securely attached to the server tray. The server tray may include a locking mechanism, which may be embodied as one or more pivoting handles proximate a front panel of the server tray that can pivot between a locking position when in the rack, and an unlocking position when the server tray is to be removed from the rack. In various embodiments, a server tray may be configured for tray eject detection to improve disconnection of electrical power between the server tray and the busbar of the server rack. The tray eject detection may be associated with the pivoting handles in some embodiments, for example, to detect when the handle is pivoted to the unlocking position prior to moving the server tray out of the rack and consequently disconnecting the bus bar connector from the server rack's power supply. By detecting the tray ejection before electrical power dissipates from the server tray, the server tray may execute a short shut-down procedure to preserve data integrity and to prevent potential hardware damage resulting from untimely disconnection of the server tray from the power supply.

According to an aspect of the present disclosure, a server tray is provided. In an example embodiment, the server tray includes a sensing element and a controller circuit. In some embodiments, the sensing element is configured to detect initiation of a power supply removal. In some embodiments, the controller circuit is configured to initiate a controlled power down sequence for the server tray responsive to a defined eject state being detected by the sensing element.

In some embodiments, the sensing element is located at a tray handle of the server tray. In some embodiments, the sensing element is a pressure switch configured to contact a portion of the tray handle when a power supply of a server rack is attached to the server tray. In some embodiments, the sensing element is a rotary switch configured to detect a position of the tray handle. In some embodiments, the sensing element is an accelerometer configured to detect movement of the tray handle. In some embodiments, the sensing element is a light detector configured to detect light when the tray handle satisfies the defined eject state. In some embodiments, the sensing element is a capacitor-based sensing element configured to detect a change in stored electrical charge in response to the defined eject state being satisfied.

In some embodiments, the sensing element is a first sensing element located at a first tray handle of the server tray and the server tray further comprises a second sensing element. In some embodiments, the second sensing element is located at a second tray handle of the server tray and configured to detect initiation of the power supply removal. In some embodiments, the controller circuit is configured to initiate the controlled power down sequence for the server tray responsive to the defined eject state being detected by the second sensing element.

In some embodiments, the controller circuit is configured to provide the controlled power down sequence for a defined interval of time to maintain power for the server tray for the defined interval of time.

According to another aspect of the present disclosure, a processing system is provided. In an example embodiment, the processing system comprises a server rack and one or more server trays. In some embodiments, the one or more server trays are supported within the server rack. In some embodiments, at least one server tray of the one or more server trays comprises a sensing element and a controller circuit. In some embodiments, the sensing element is configured to detect initiation of a power supply removal. In some embodiments, the controller circuit is configured to initiate a controlled power down sequence for the at least one server tray responsive to a defined eject state being detected by the sensing element.

In some embodiments, the sensing element is located at a tray handle of the at least one server tray. In some embodiments, the sensing element is a pressure switch configured to contact a portion of the tray handle when a power supply of the server rack is attached to the at least one server tray. In some embodiments, the sensing element is a rotary switch configured to detect a position of the tray handle. In some embodiments, the sensing element is an accelerometer configured to detect movement of the tray handle. In some embodiments, the sensing element is a light detector configured to detect light when the tray handle satisfies the defined eject state. In some embodiments, the sensing element is a capacitor-based sensing element configured to detect a change in stored electrical charge in response to the defined eject state being satisfied. In some embodiments, the controller circuit is configured to provide the controlled power down sequence for a defined interval of time to maintain power for the at least one server tray for the defined interval of time.

According to another aspect of the present disclosure, a method is provided. In an example embodiment, the method comprises receiving a power sequencing control signal responsive to a defined eject state being detected by a sensing element configured to detect initiation of a power supply removal; and initiating a controlled power down sequence for the server tray based at least in part on the power sequencing control signal.

### BRIEF DESCRIPTION OF THE SEVERAL VIEWS OF THE DRAWINGS

Reference will now be made to the accompanying drawings, which are not necessarily drawn to scale, and wherein:

FIG. 1A schematically illustrates an example server tray, in accordance with one or more embodiments;

FIG. 1B schematically illustrates an example server rack comprising a server tray, in accordance with one or more embodiments;

FIG. 2 is an external view of a server tray, in accordance with one or more embodiments;

FIG. 3 is a partial view of a server tray, in accordance with one or more embodiments;

FIG. 4 illustrates an example server rack comprising a server tray mounted at a tray position, in accordance with one or more embodiments;

FIG. 5 is a block diagram of an example system that may include one or more datacenters including server racks, in accordance with one or more embodiments;

FIG. 6 is a schematic diagram of an example datacenter that may include one or more optical interconnects, in accordance with one or more embodiments;

FIG. 7 is a block diagram that schematically illustrates a computing system that may include one or more trays mounted in one or more server racks of various embodiments;

FIG. 8 illustrates an example computing environment, in accordance with one or more embodiments;

FIG. 9 illustrates another example computer system that may include one or more trays mounted within one or more server racks, in accordance with one or more embodiments; and

FIG. 10 illustrates a process depicting example operations for tray eject detection, in accordance with one or more embodiments.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

In datacenters, server trays hosting computing resources, switches, and/or the like tend to be mounted within server racks. A server rack includes a busbar configured to deliver electrical power to the server trays. For example, the server trays comprise a busbar connector configured to electrically couple components of the server tray to the busbar. Conventionally, electrical power received at the busbar connector is carried by cabling over the modules of the server tray to a power distribution circuit located on the printed circuit board (PCB) of the server tray. The power distribution circuit then distributes electrical power to the modules of the server tray. When connected with the bus bar, the power distribution circuit and the modules function to enable the server tray to perform processing tasks as a part of the datacenter. In some server trays, part of that functionality is to power cooling components (e.g., fans) that ensure that various server tray components do not overheat. However, if the server tray is removed from the server rack (and consequently disconnected from the electrical power supply of the busbar) during normal operation of the server tray, certain components of the server tray are at risk of damage, for example, due to excess heat that cannot be quickly dissipated or due to sudden changes in voltage applied to sensitive electrical components. For example, the power distribution circuit generally includes components that may fail and/or suffer damage while conditioning the high voltage and/or current electrical power if the power supply is suddenly removed.

Therefore, when a server tray is removed from a server rack, it is desirable for a server tray to utilize power sequencing to satisfy processor-specific power sequencing requirements for the server tray. For example, when a server tray is removed from a server rack, power sequencing for the server tray may be based on a “short/sense pin” that is physically shorter than other pins (e.g., power pins, signal pins, etc.) on the same connector (e.g., a busbar clip) that attaches the server tray to a power supply of a server rack to allow an adequate amount of time for the server tray to reset before the power supply is disconnected from the server tray. However, when the server tray is removed from the server rack, this type of power sequencing technique may not provide compute resources of the server tray with adequate time to reset before a power supply of the server rack is disconnected from the server tray. As such, conventional server trays are susceptible to data corruption and/or hardware damage when being removed from a server rack during a hot swap scenario where the server tray is removed from the server rack without powering down the server tray prior to the removal of the server tray from the server rack. Technical problems exist for determining with certainty if an electrical power source will be imminently disconnected from the server tray, to enable the server tray to perform one or more power down requirements prior to total power loss and thereby minimize potential damage to the components of the server tray that could be caused by a sudden power disconnection.

Various embodiments provide a server tray configured for tray eject detection to enable improved power sequencing for the server tray being removed from a server rack. Accordingly, a server tray may be provided with enhanced functionality in a datacenter environment to minimize data corruption and/or hardware damage for the server tray when being disconnected from a power supply of a server rack.

Various embodiments provide technical solutions to these technical problems. For example, various embodiments provide a technical solution to enable improved power sequencing for a server tray being removed from a server rack by sensing a power disconnect process prior to total power loss at the server rack. For example, the server rack may utilize a sensing element for a tray handle of the server tray. In various embodiments, when the sensing element detects that the tray handle is open (e.g., the server tray is being removed from a server rack), a controlled (e.g., safe) power down sequence for the server tray may be provided for a defined interval of time to enable sufficient time for the server tray to reset. In a specific and non-limiting example, a controller utilizes a deep power cycle circuit to disable a 54V hot-swap controller for 8 seconds. In some embodiments, the sensing element may be located at a tray handle of the server tray. The sensing element may be a pressure switch, a rotational switch, an accelerometer, a light detector, or a capacitor-based sensing element, or another type of sensing element capable of detecting that a tray handle is open. For example, the sensing element may be a pressure switch configured to contact a portion of the tray handle when a power supply is attached to the server tray. In some embodiments, a capacitor or other capacitance element of the server tray may act as an alternate power source to maintain operation of the server tray during the controlled power down sequence. Additionally, the controlled power down sequence may be provided for a defined interval of time to maintain server tray power for the defined interval of time. In some embodiments, the server tray may include two tray handles with respective sensing elements to enable the controlled power down sequence. In some embodiments, a deep power cycle circuit of the server tray is utilized for disabling a hot-swap controller of the server tray to enable the controlled power down sequence.

In various embodiments, the server rack is an Open Compute Project (OCP) server rack or another type of server rack configured with a power zone for providing power to various server trays mounted in the server rack. For example, the server rack may include a busbar that is Open Rack Version 3 (ORV3) standards compliant, enabling powering of a variety of trays mounted within the server rack via a power supply associated with a power zone of the server rack. In various embodiments, chassis and/or rails of the server rack may define and/or comprise support structures for server trays. As such a variety of server trays may be mounted and/or supported by the support structures.

Thus, various embodiments provide a server tray configured for tray eject detection to enable improved power sequencing for the server tray being removed from a server rack. As a result, various embodiments provide a server rack and/or a server tray that may be used to provide a highly configurable datacenter optimized for efficiency, reliability, minimized system downtime, and/or improved performance. Various embodiments accordingly provide improvements to the fields of server trays, server racks, datacenters, datacenter architecture configurability, and/or the like.

### Processing Systems

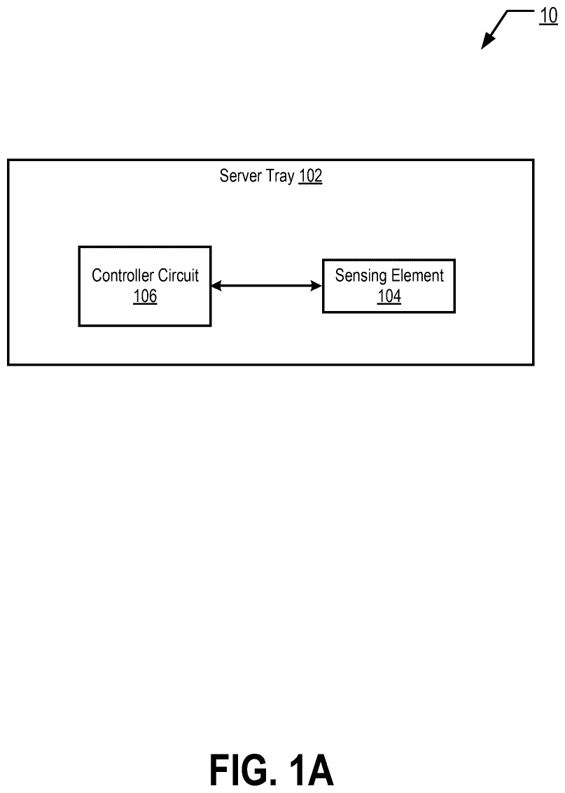

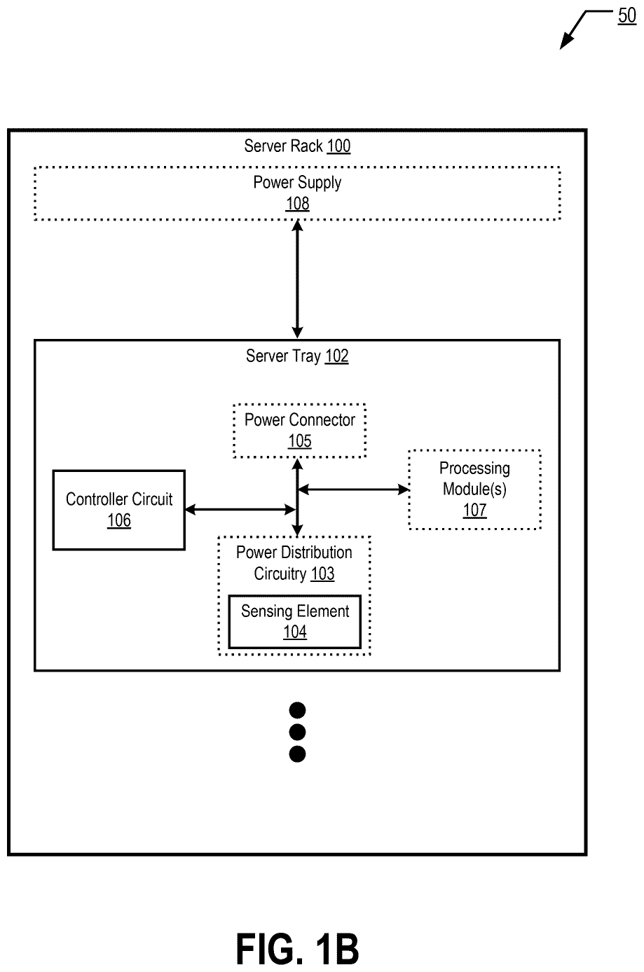

FIG. 1A illustrates a processing system 10 comprising a server tray 102 in accordance with one or more embodiments of the present disclosure. The processing system 10 may be one of a plurality of processing systems 10 within a datacenter. The server tray 102 comprises at least a sensing element 104 and a controller circuit 106. The sensing element 104 may be configured to detect initiation of a power supply removal. The controller circuit 106 may be configured to initiate a controlled power down sequence for the server tray 102 responsive to a defined eject state being detected by the sensing element 104. In some embodiments, the controller circuit 106 is configured to provide the controlled power down sequence for a defined interval of time to maintain power for the server tray 102 for the defined interval of time.

In some embodiments, the sensing element 104 is located at a tray handle of the server tray 102. For example, the sensing element 104 may be a pressure switch configured to contact a portion of the tray handle when a power supply of a server rack is attached to the server tray 102. In another example, the sensing element 104 is a rotary switch configured to detect a position of the tray handle. In yet another example, the sensing element 104 is an accelerometer configured to detect movement of the tray handle. In yet another example, the sensing element 104 is a light detector configured to detect light when the tray handle satisfies the defined eject state. In yet another example, the sensing element 104 is a capacitor-based sensing element configured to detect a change in stored electrical charge in response to the defined eject state being satisfied. However, it is to be appreciated that, in some embodiments, the sensing element 104 is configured as a different type of sensing element configured to detect initiation of a power supply removal.

FIG. 1B illustrates a processing system 50 comprising a server rack 100 in accordance with one or more embodiments of the present disclosure. The processing system 50 may be one of a plurality of processing systems 50 within a datacenter. The server rack 100 includes the server tray 102 and a power supply 108. The server rack 100 may transmit power from the power supply 108 of the server rack 100 to respective server trays of the server rack 100. For example, the server rack 100 may transmit power from the power supply 108 to the server tray 102, as discussed further herein. In various embodiments, the server tray 102 may be electrically coupled to the power supply 108 via a power connector 105. For example, the power connector 105 may include a set of contact pins (e.g., power pins, signal pins, etc.) that attaches the server tray 102 to the power supply 108 to provide electric power to the server tray 102. In some embodiments, the power connector 105 is a busbar connector (e.g., a busbar clip). The server tray 102 additionally includes processing module(s) 107, for example application specific integrated circuit (ASIC). For example, the processor may be or include one or more of an Integrated Circuit (IC) chip, a microprocessor, a Central Processing Unit (CPU), a Graphics Processing Unit (GPU), a Data Processing Unit (DPU), a Field Programmable Gate Array (FPGA), a network interface controller (NIC), an ASIC, combinations thereof, and the like. The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted.

The server tray 102 additionally comprises power distribution circuitry 103, the sensing element 104, and the controller circuit 106. In an embodiment, the power distribution circuitry 103 comprises the sensing element 104. In another embodiment, the sensing element 104 is communicatively coupled to the power distribution circuitry 103. The power distribution circuitry 103 may distribute electric power provided by the power supply 108 to the processing module(s) 107 and/or one or more other modules of the server tray 102. In some embodiments, the power distribution circuitry 103 may condition the electric power to satisfy power requirements for the processing module(s) 107 and/or one or more other modules of the server tray 102. In some embodiments, the power distribution circuitry 103 is implemented on a printed circuit board (PCB) and/or a motherboard of the server tray 102.

In some embodiments, the sensing element 104 may be located at a tray handle of the server tray 102. In some embodiments, the server rack 100 includes multiple server trays. For example, the server tray 102 and one or more other server trays may be mounted within the server rack 100. In some embodiments, the server tray 102 includes multiple sensing elements. For example, a sensing element may be located at respective tray handles of the server tray 102 for embodiments where the server tray 102 includes multiple tray handles. In other embodiments, the sensing element may detect a voltage change or current change within one or more circuits of the power distribution circuitry 103, for example, to detect when a voltage dissipates from the inherent capacitance of the power distribution circuitry 103 as a result of disconnection of the server tray 102 from the bus bar. In an embodiment, the controller circuit 106 is a Field-Programmable Gate Array (FPGA). In another embodiments, the controller circuit 106 is a Complex Programmable Logic Device (CPLD). In yet another embodiment, the controller circuit 106 is an Application-Specific Integrated Circuits (ASIC). However, it is to be appreciated that, in certain embodiments, the controller circuit 106 is configured as a different type of circuit and/or the controller circuit 106 may be embodied as the processing module(s) 107.

In some embodiments, the server tray 102 provides a structure for housing circuitry components of the server tray 102 such as the power distribution circuitry 103, the controller circuit 106, and/or the processing module(s) 107. In various embodiments, the sensing element 104 and the controller circuit 106 may be utilized to allow an adequate amount of time for the processing module(s) 107 of the server tray 102 to reset before the power supply is disconnected from the processing module(s) 107. As such, data corruption and/or hardware damage for the processing module(s) 107 may be mitigated when the server tray 102 is removed from the server rack 100.

In some embodiments, the server rack 100 may be located within a datacenter. For example, the datacenter may include the server rack 100 and one or more other server racks comprising respective pluralities of server trays mounted therein. A server tray such as the server tray 102 may include various components that communicate with one another via a fast and robust communication infrastructure. For example, optical interconnects may enable communication between various server trays and/or server racks. In some embodiments, the datacenter may comprise a collection of network devices, such as network switches (e.g., Ethernet switches, IP routers, multiservice platforms, various transmission network elements, legacy communication equipment, or in any other suitable communication system) connected with a collection of servers or compute nodes. A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, synchronous transport signal (STS), time-slot interchange (TSI), shared memory, buffered crossbar, any other suitable blocking or non-blocking architecture, or any applicable mixed architecture thereof. A switch fabric is realized in typical embodiments by hardware, which may comprise FPGAs, CPLDs, ASICs, and/or bus interconnects. The datacenter may adhere to a networking topology (e.g., a hierarchal networking topology), such as a fat tree topology, a Slim Fly topology, a Dragonfly topology, and/or the like. The datacenter may route traffic amongst the network switches and servers therein, and at least one layer of the topology in the datacenter is coupled to the communication network to allow networking traffic to flow between the datacenter and the network device(s).

In some embodiments, optical interconnects include transceivers used to connect network-connected devices (e.g., remote client switches, network adapters such as Network Interface controllers (NICs) and Host Channel Adapters (HCAs), Smart-NICs (NICs comprising embedded CPUs), network-enabled Graphics Processing Units (GPUs), and the like). The terms “network-connected device” and “network device” are used interchangeably herein. In certain embodiments, an optical interconnect includes a substrate, one or more optical waveguides, one or more first micro-lenses, one or more second micro-lenses, and first and second mechanical fixtures.

A “node” as described herein may refer to a network switch to which a plurality of computer processing units (CPUs), graphical processing units (GPUs), data processing units (DPUs), or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode cores. Optical fibers can extend contiguously and uninterrupted between node or send/receive pairs (e.g., via pass-through connections) or include two or more fibers connected via fiber-to-fiber connections such that the fibers function or perform as a single fiber.

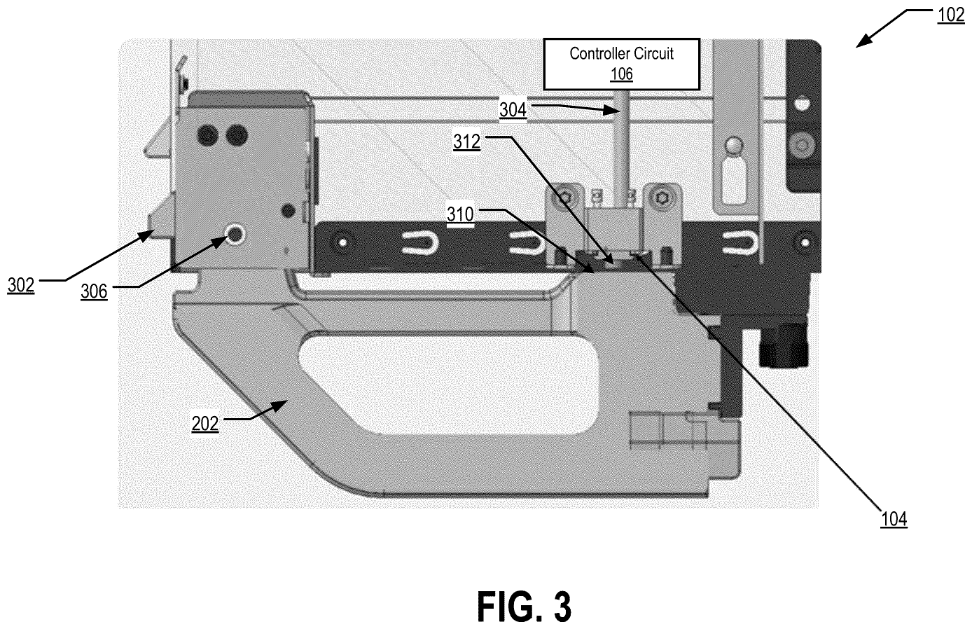

In various embodiments, the server rack 100 may be configured to receive and/or accommodate a variety of server trays including the server tray 102. For example, the server rack 100 may accommodate a server tray 102 embodied as shown in FIG. 3, which is an optical switch tray configured to optically connect a plurality of compute trays each having one or more processing resources. The server rack 100 may additionally accommodate server trays 102 embodied as compute trays. Although FIG. 3 specifically illustrates a switch tray, it should be understood that the features and components discussed herein may be embodied as components of a compute tray. In certain embodiments, the server rack 100 includes a chassis and rails that are in accordance with the Electronic Industries Alliance (EIA) standards. The server rack may also include a cable cartridge in accordance with EIA standards and/or a busbar that is Open Rack Version 3 (ORV3) standards compliant.

The controller circuit 106 may be configured to initiate a controlled power down sequence for the server tray 102 responsive to a defined eject state being detected by the sensing element. For example, the controller circuit 106 may be configured to initiate a controlled power down sequence for the processing module(s) 107 of the server tray 102 responsive to a defined eject state being detected by the sensing element 104. The defined eject state may be a sensing state associated with the sensing element 104 that indicates removal of the server tray 102 from the server rack 100.

In some embodiments, the controller circuit 106 may communicate with a hot-swap controller of the server tray 102 to enable the controlled power down sequence. For example, the hot-swap controller may be configured to manage removal of the server tray 102 during hot-swappable operations associated with the server tray 102. In some embodiments, the hot-swap controller may control a time evolution of electrical power passing to the processing module(s) 107. In some embodiments, the hot-swap controller includes one or more metal-oxide-semiconductor field effect transistors (MOSFETs) to facilitate the control of the time evolution of electrical power passing to the processing module(s) 107. In some embodiments, the hot-swap controller may execute power sequencing to enable or disable power to one or more computing modules of the server tray 102. In some embodiments, the controller circuit 106 may transmit a control signal to the hot-swap controller to initiate the controlled power down sequence. In some embodiments, the controller circuit 106 may disable functionality of the hot-swap controller for the defined interval of time to enable the controlled power down sequence. In some embodiments, a capacitance, resistance, and/or the like provided via the hot-swap controller may be configured to smooth the time evolution of electrical power received from the busbar via the power connector 105 by spreading out in time any changes in voltage and/or current in the electrical power provided by the power connector 105. For example, the hot-swap controller may be configured to control inrush current when the power connector 105 electrical communication is disconnected with respect to the busbar.

### Server Tray

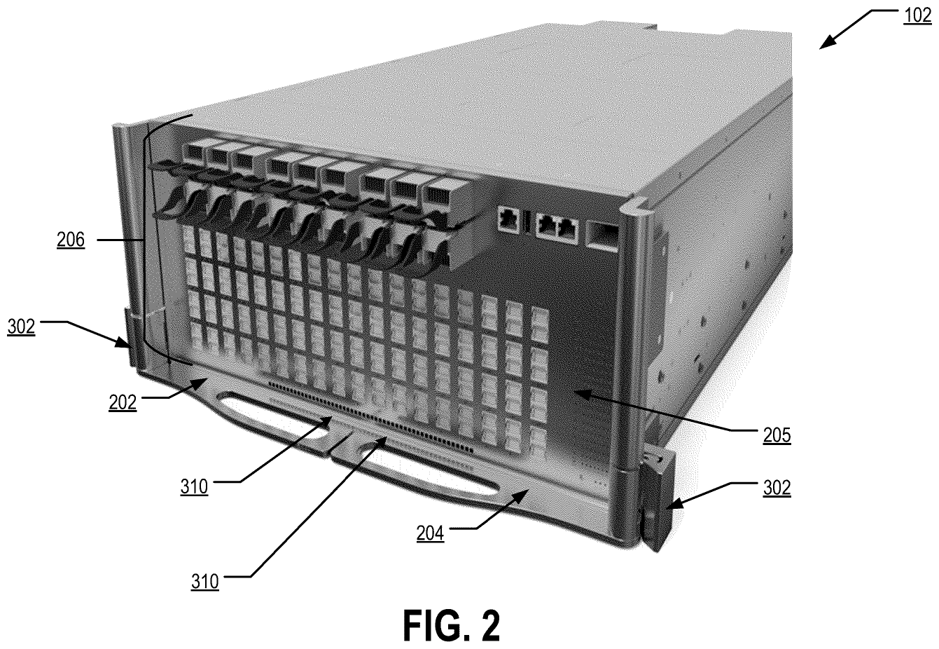

FIG. 2 provides an external view of the server tray 102 in accordance with one or more embodiments of the present disclosure. FIG. 2 shows a switch tray having a plurality of connector ports on a front panel of the tray, however it should be understood that analogous eject detection features and methods may be implemented for compute trays comprising a plurality of processing resources. As illustrated in FIG. 2, the server tray 102 includes a tray handle 202 and a tray handle 204. However, it is to be appreciated that, in certain embodiments, the server tray 102 includes a single tray handle (or more than 2 tray handles). The tray handle 202 and the tray handle 204 may be implemented as a locking mechanism to mount the server tray 102 to the server rack 100. In some embodiments, the tray handle 202 may be a pivoting tray handle proximate a front panel 205 of the server tray 102. For example, the tray handle 202 may pivot between a locking position when mounted to the server rack 100, and an unlocking position when the server tray 102 is to be removed from the server rack 100. Similarly, the tray handle 204 may be a pivoting tray handle proximate a front panel 205 of the server tray 102. For example, the tray handle 204 may pivot between a locking position when mounted to the server rack 100, and an unlocking position when the server tray 102 is to be removed from the server rack 100. In some embodiments, the locking position may enable the server tray 102 to be locked into the server rack 100 such that the power connector 105 of the server tray 102 remains connected with the electrical power supply. For example, when in the locking position, portions of the tray handle 202, 204 on an outside of the handle pivot point may extend beyond the width of the server tray 102, and may be configured to engage corresponding features on a server rack, to lock the server tray 102 into the server rack.

In various embodiments, the server tray 102 may be configured for tray eject detection to improve disconnection of electrical power between the server tray 102 and the power supply 108 of the server rack 100. The tray eject detection may be enabled via at least one sensing element (e.g., the sensing element 104, as shown in FIG. 3) located proximate to the tray handle 202 and/or the tray handle 204. For example, the at least one sensing element (e.g., the sensing element 104) may detect when the tray handle 202 and/or the tray handle 204 is pivoted to an unlocking position prior to moving the server tray 102 out of the server rack 100 and consequently disconnecting the server tray 102 from the power supply 108 of the server rack 100. By detecting the tray ejection before electrical power dissipates from the server tray 102, the server tray 102 may execute a shut-down procedure to preserve data integrity and/or to prevent potential damage of the processing module(s) resulting from untimely disconnection of the server tray 102 from the power supply 108.

The at least one sensing element may be configured to detect initiation of a power supply removal when the tray handle 202 and/or the tray handle 204 is pivoted to an unlocking position. In an embodiment, a single sensing element (e.g., the sensing element 104) may be located proximate to either the tray handle 202 or the tray handle 204. Additionally, the single sensing element may be communicatively coupled to the controller circuit 106 to initiate a controlled power down sequence for the server tray 102 responsive to a defined eject state being detected by the single sensing element. In another embodiment, a first sensing element (e.g., the sensing element 104) of the server tray 102 may be located proximate to the tray handle 202 to enable sensing of an open state and a closed state for the tray handle 202. Additionally, a second sensing element (e.g., the sensing element 104) of the server tray 102 may be located proximate to the tray handle 204 to enable sensing of an open state and a closed state for the tray handle 204. The first sensing element associated with the tray handle 202 and the second sensing element associated with the tray handle 204 may be communicatively coupled to the controller circuit 106 to initiate a controlled power down sequence for the server tray 102 responsive to a defined eject state being detected by the first sensing element and/or the second sensing element.

The server tray 102 may additionally include a set of cable connector ports 206 at the front panel 205 of the server tray 102. For example, the set of cable connector ports 206 may include data connector ports, networking ports, USB ports, and/or one more other types of ports to enable cabling with respect to the server tray 102. In some embodiments, the set of cable connector ports 206 include a set of ports for one or more network adaptors. In some embodiments, the set of cable connector ports 206 include a set of ports for one or more Network Interface Controllers (NICs). In some embodiments, the set of cable connector ports 206 include a set of ports for Quad Small Form-factor Pluggable (QSFP) cable connectors. As discussed herein, the illustrated server tray 102 is a switch tray, however compute trays comprising a plurality of processing resources may have analogous structural components of a housing, front panel, and pivoting handles, and accordingly the sensing element 104 may operate in a similar manner for other server tray configurations.

FIG. 3 provides a partial cutaway view of the server tray 102 in accordance with one or more embodiments of the present disclosure. As illustrated in FIG. 3, the server tray 102 includes at least the tray handle 202. In some embodiments, the sensing element 104 of the server tray 102 may be located proximate to the tray handle 202 to enable sensing of an open state and a closed state for the tray handle 202. In some embodiments, the sensing element 104 may be communicatively coupled to the controller circuit 106 via a circuit communication bus 304.

The sensing element 104 may be configured to detect initiation of a power supply removal based on positioning of the tray handle 202. Additionally, the controller circuit 106 may be configured to initiate a controlled power down sequence for the server tray 102 responsive to a defined eject state being detected by the sensing element 104.

The tray handle 202 may be a pivoting tray handle that pivots between a locking position when mounted to the server rack 100 via locking mechanism 302, and an unlocking position when the locking mechanism 302 of the server tray 102 is disengaged from the server rack 100. In some embodiments, the tray handle 202 may pivot with respect to a pivot point 306 of the server tray 102 to enable the locking position and the unlocking position associated with the locking mechanism 302. In some embodiments, the defined eject state detected by the sensing element 104 may be associated with an unlocking position when the locking mechanism 302 of the server tray 102 is disengaged from the server rack 100. For example, when the tray handle 202 is opened and/or pivoted via the pivot point 306 such that the locking mechanism 302 is in an unlocking position, the sensing element 104 may detect the defined eject state that corresponds to the tray handle 202 being opened.

In some embodiments, the sensing element 104 may be a sensing element for the tray handle 202 of the server tray 102 to enable improved power sequencing during hot swap removal of the server tray 102 from the server rack 100. For example, when the sensing element 104 detects that the tray handle 202 is open (e.g., the server tray 102 is being removed from a server rack 100), a controlled power down sequence for the server tray 102 may be provided via the controller circuit 106. The controller circuit 106 may provide the controlled power down sequence for a defined interval of time to enable sufficient time for the server tray 102 to reset. For example, the controlled power down sequence may be provided for a defined interval of time to maintain power for the server tray 102 for the defined interval of time. The controlled power down sequence may correspond to a power sequencing process executed by the server tray 102 to satisfy processor-specific power sequencing requirements for the server tray 102 and/or the processing module(s) 107.

The sensing element 104 may be a pressure switch, a rotational switch, an accelerometer, a light detector, or a capacitor-based sensing element, or another type of sensing element capable of detecting that the tray handle 202 is open. For example, the sensing element 104 may be a pressure switch located at a handle contact point 310 configured to contact a portion of the tray handle 202 when the power supply 108 is electrically coupled to the server tray 102. Specifically, the pressure switch comprises a spring-loaded button 312 extending out of the front surface of the tray at the handle contact point 310. When the tray handle 202 is in the closed position, the tray handle 202 depresses the spring-loaded button 312, which provides an indication to the sensing element 104 that the server tray 102 should remain in a normal operating mode. However, when the tray handle 202 is rotated to the open position, the spring-loaded button 312 extends out of the front surface of the server tray 102, providing a signal to the sensing element 104 that the server tray 102 is imminently to be removed. Where a server tray 102 comprises multiple handles each with its own sensing element 104 (e.g., pressure switch), the server tray 102 may await for all of the sensing elements 104 to provide a signal indicating imminent removal of the power supply before initiating a shutdown sequence.

In another example, the sensing element 104 may be a rotational switch (e.g., a rotary switch) located at the pivot point 306 with a contact arm configured to detect a position of the tray handle 202. The rotational switch may be indexed, such that the rotational switch recognizes the position of the tray handle 202 between the closed position and the open position. Accordingly, the sensing element 104 may operate similarly to that described above (for the pressure switch embodiment), by recognizing when the tray handle 202 is rotated to the open position.

In another example, the sensing element 104 may be an accelerometer (e.g., a micro-electromechanical systems (MEMS) accelerometer) attached to the tray handle 202 configured to detect movement of the tray handle 202. The accelerometer may be configured to detect a direction of movement of the tray handle 202. Upon detecting movement of the tray handle 202 in a direction from the closed position to the open position, the sensing element 104 may be configured to signal imminent removal of the server tray 102.

In yet another example, the sensing element 104 may be a light detector (e.g., a light sensor) configured to detect light when the tray handle 202 is open. The light detector may be positioned at the handle contact point 310 on the front surface of the server tray 102. While the tray handle 202 is positioned in the closed position, the tray handle 202 blocks the light sensor. When the tray handle 202 is moved to the open position, the light sensor detects light, which indicates imminent removal of the server tray 102 using the sensing element.

In yet another example, the sensing element 104 may be capacitor-based sensing element configured to detect when the tray has been removed from the power supply, but before all voltage has dissipated from the power supply circuit. In some embodiments, the power supply circuit has a natural capacitance to enable the server tray 102 to continue operating for a short period of time (e.g., 0.5 seconds, 1 second, 2 seconds, 5 seconds) after removal of the power supply. Once the capacitor-based sensing element detects a change in voltage in the circuit indicating removal of the power supply, the sensing element may signal to begin the shut-down sequence. is open based on a capacitance-level of a capacitance element of the server tray 102. As such, the controller circuit 106 may be configured to initiate the controlled power down sequence for the server tray 102 and/or the processing module(s) 107 responsive to a defined eject state being detected by the sensing element 104.

In some embodiments, the defined eject state may correspond to a defined voltage level and/or a defined current level. The defined eject state may include a defined pressure event, a defined rotary event, a defined accelerometer event, a defined light detection event, a defined capacitor-based event, or another type of defined eject state that indicates that the tray handle 202 is opened and/or that the locking mechanism 302 is in an unlocking position. For example, the defined pressure event may correspond to a pressure switch being released when the tray handle 202 is open such that the pressure switch is no longer in contact with the tray handle 202. In another example, the defined rotary event may correspond to an indexed rotational sensor determining that a contact arm of the indexed rotational sensor is rotated to a defined position based on the tray handle 202 being opened such that the contact arm is moved away from a locked position associated with the tray handle 202. In yet another example, the defined accelerometer event may correspond to a certain degree and/or direction of motion being detected by an accelerometer to indicate that the tray handle 202 is being moved in a defined direction (e.g., the tray handle 202 is opened) such that the tray handle 202 is no longer in a locked position. In yet another example, the defined light detection event may correspond to detection of light by a light sensor that indicates that the tray handle 202 is being opened and/or moved away from a locked position where the tray handle 202 covers the light sensor. In yet another example, the defined capacitor-based event may correspond to a level of electrical charge of a capacitance element satisfying a defined electrical charge threshold value to indicate that the tray handle 202 is open and/or that the server tray 102 is disconnected from the power supply 108.

The capacitance element associated with the defined capacitor-based event may be a capacitor of the server tray 102 that stores an electrical charge. In some embodiments, the capacitor is a capacitor or other circuit element of the power distribution circuitry 103. Additionally, the capacitor-based sensing element may be a sensor that monitors a state of stored electrical charge in the capacitor to identify the defined capacitor-based event. In some embodiments, the capacitor-based sensing element may utilize stored electrical charge of the capacitor to enable the server tray 102 to operate for the defined interval of time when the server tray 102 is removed from the server rack 100. For instance, the capacitor may remain fully charged when the server tray 102 is mounted in the server rack 100 and powered by the power supply 108. However, when the server tray 102 is removed from the server rack 100, the capacitor may act as a short-term battery to maintain operation of the server tray 102 for the defined interval of time as power stored in the capacitor discharges. In some embodiments, the controller circuit 106 may utilize a sensor (e.g., a current meter and/or a voltage meter) to detect discharge of the power stored in the capacitor and initiate a power-down mode for the server tray 102 during the defined interval of time.

### Server Rack

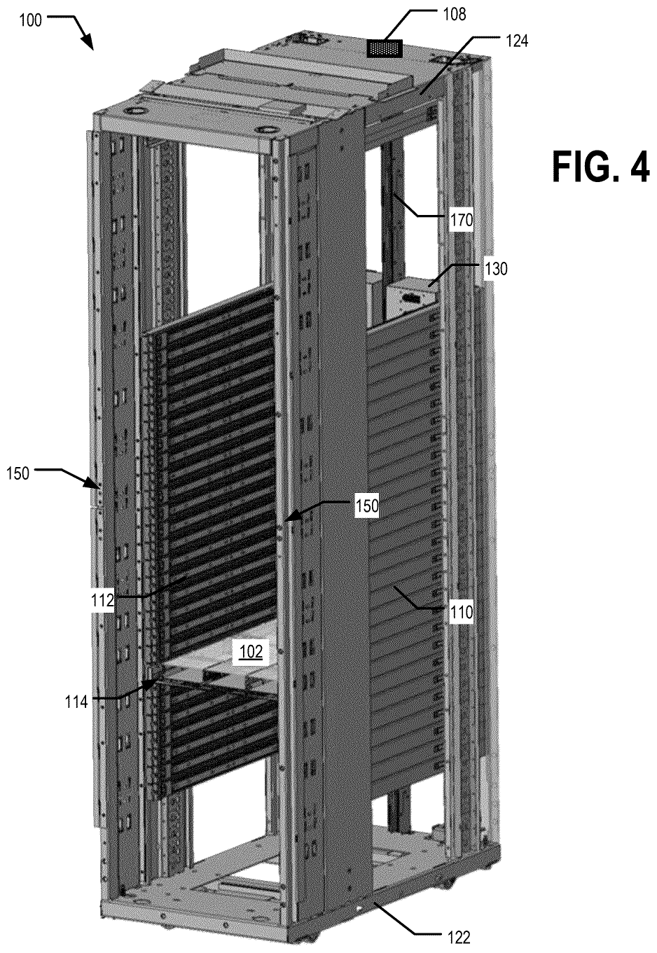

FIG. 4 provides a view of the server rack 100 in accordance with one or more embodiments of the present disclosure. In some embodiments, the server rack 100 includes a plurality of support structures 112. The plurality of support structures 112 are each configured to support a server tray (e.g., the server tray 102). Each support structure accommodates a selected one of air or liquid cooling of the tray supported by the support structure. In various embodiments, the server rack 100 is configured to accommodate server trays configured for liquid cooling and server trays configured for air cooling at any tray location. For example, each of the support structures 112 are configured to accommodate a selected one of air or liquid cooling of the server tray 102.

In various embodiments, the server rack 100 includes a busbar 170. In certain embodiments, the busbar 170 is disposed on the backside 101A of the server rack 100. For example, the busbar 170 may extend at least a portion of the way between a bottom frame 122 and a top frame 124 along the backside of the server rack 100. In various embodiments, the busbar 170 is configured to provide electrical power to trays (e.g., the tray 102) mounted within the server rack 100. In some embodiments, the busbar 170 is configured to provide DC electrical power to the server tray 102 and/or one or more other server trays mounted within the server rack 100. For example, the busbar 170 may be in electrical communication with the power supply 108 housed in a top frame 124 and/or another location within the server rack 100 such that the busbar 170 is supplied with an appropriate current or voltage differential for powering the server tray 102 and/or one or more other server trays mounted within the server rack 100. In various embodiments, the busbar 170 is in compliance with the ORV3 standards.

The server rack 100 may transmit power from the power supply 108 of the server rack 100 to respective server trays of the server rack 100 via the busbar 170. For example, the server rack 100 may transmit power from the power supply 108 to the server tray 102 via the busbar 170, as discussed herein. The server tray 102 and its integrated sensing element 104 may be utilized to enable power sequencing for the server tray 102 with respect to the power supply 108, for example when the server tray 102 is removed from the server rack 100.

In some embodiments, the server tray 102 may include the power connector 105 to electrically couple components of the server tray 102 to the busbar 170. In some embodiments, electrical power received at the power connector 105 is carried by cabling over the modules of the server tray 102 to the power distribution circuitry 103. The power distribution circuitry 103 then distributes electrical power to the modules of the server tray 102. In some embodiments, the power distribution circuitry 103 may be configured to condition high voltage and/or current electrical power provided by the busbar.

In some embodiments, the server tray 102 may comprise the power connector 105 to establish electrical communication with the busbar 170 of the server rack 100 so as to provide electrical power to the processing module(s) 107 of the server tray 102. In some embodiments, the power connector 105 is configured to connected to the busbar 170 (e.g., in accordance with ORV3) using paddles of the power connector 105 such that the busbar 170 is in electrical communication with contacts of the power connector 105. In an example embodiment, the paddles and/or the contacts are configured to provide floating electrical connection with the busbar 170. For example, the paddles and/or contacts may be configured to enable movement of the power connector 105 with respect to the busbar 170 without the power connector 105 abrading the busbar 170. In some embodiments, the power connector 105 may be configured to enable the server tray 102 to move within a movement range without modifying the electrical contact and/or physical contact between the contacts and the busbar 170.

In some embodiments, the sensing element 104 is configured to detect initiation of a power supply removal from the busbar 107. For example, the sensing element 104 may detect initiation of a power supply removal from the power supply 108 that supplies electric power to the server tray 102 via the busbar 170. In some embodiments, the sensing element 104 may detect initiation of a power supply removal based on the contacts of the power connector 105 being disconnected from the busbar 170 of the server rack 100.

In some embodiments, when the sensing element 104 detects that a tray handle (e.g., the tray handle 202 and/or the tray handle 204) of the server tray 102 is open such that the server tray 102 is being disconnected from the busbar 170, a controlled power down sequence for the server tray 102 may be provided via the controller circuit 106. The controller circuit 106 may provide the controlled power down sequence for a defined interval of time to enable sufficient time for the server tray 102 to reset. For example, the controlled power down sequence may be provided for a defined interval of time to maintain power for the server tray 102 for the defined interval of time.

In various embodiments, the server rack 100 includes a cable cartridge 130. In various embodiments, the cable cartridge 130 is mounted to a backside of the server rack 100. The cable cartridge 130 extends at least a portion of the way between the bottom frame 122 and the top frame 124 of the server rack 100. The cable cartridge 130 may include a plurality of cable connectors. Each cable connector may correspond to a respective tray location 114 and may be configured to connect with a corresponding cable connector disposed on a backside of the server tray 102 inserted into and/or mounted at the tray location 114. For example, the cable cartridge 130 includes a plurality of electrical and/or optical cables configured to facilitate communication between the server tray 102 and/or one or more other server trays mounted within the server rack 100 according to a desired topology and/or connectivity. In certain embodiments, the cable cartridge 130 is independent of the busbar 170. For example, the cable cartridge 130 may be removed from the server rack 100 and replaced with a different cable cartridge 130 without affecting or removing the busbar 170. In various embodiments, the cable cartridge and/or cable connectors are in compliance with EIA standards.

In various embodiments, the server rack 100 includes a chassis 110. In various embodiments, the chassis 110 extends at least a portion of the way between the bottom frame 122 and the top frame 124 of the server rack 100 on the lateral sides of the server rack 100. In various embodiments, the chassis 110 includes a plurality of support structures 112. The plurality of support structures 112 are each configured to support server tray (e.g., the server tray 102). For example, the plurality of support structures 112 may define a plurality of tray locations 114. Each tray location 114 is a location within the server rack 100 at which a tray may be mounted such that the tray is supported by the corresponding support structure(s) 112. In various embodiments, the chassis 110 is characterized by a one-unit pitch. Other pitches may be utilized in various embodiments. In various embodiments, the chassis 110 is compliant with EIA standards. In some embodiments, the chassis 110, the support structure(s) 112, and/or another portion of the server rack 100 may include a component 150 that engages with the locking mechanism 302 of the server tray 102 when the tray handle 202 and/or the tray handle 204 are rotated to a locking position.

In some embodiments, the server rack 100 includes a pluggable liquid cooling connector configured to enable the server tray 102 to selectively be placed into fluid communication with a liquid cooling manifold of the server rack 100. For example, the pluggable liquid cooling connector may be configured such that, at the tray location 114, the server tray 102 may be mounted such that the server tray 102 may be fluidly coupled to the pluggable liquid cooling connector(s) corresponding to the tray location. In some embodiments, the server tray 102 may include one or more integrated fans that are configured to air cool the server tray 102 and may not be fluidly coupled to the liquid cooling manifold.

### Datacenter Systems

In various embodiments, a datacenter may include the server rack 100 and/or one or more other server racks where each server rack is configured to have one or more trays (e.g., the server tray 102) mounted therein. For example, a server tray (e.g., the server tray 102) may include one or more processing units, switches, and/or other processing components. The various server trays of the server rack 100 and/or one or more other server racks may be in communication with one another according to a topology of the datacenter via cable cartridges. In some embodiments, various server racks may be in communication with one another via optical interconnects, in accordance with a topology of the datacenter. In various embodiments, the server rack 100 includes one more server trays (e.g., the server tray 102) that are air cooled (e.g., include integrated fans) and/or one or more trays (e.g., the server tray 102) that are liquid cooled (e.g., are fluidly coupled to a liquid cooling manifold of the server rack 100). In some embodiments, the server rack 100 may include a first L1 domain comprising one or more trays that are air cooled and a second L1 domain comprising one or more trays that are liquid cooled.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gbps. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

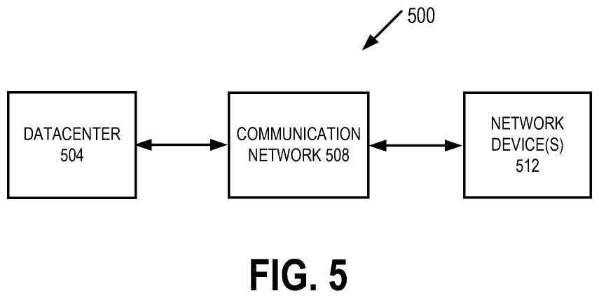

FIG. 5 provides a system 500 according to at least one example embodiment. The system 500 includes a datacenter 504, a communication network 508, and one or more network devices 512. In at least one example embodiment, the datacenter 504 corresponds to a collection of network devices, such as network switches (e.g., Ethernet switches) connected with a collection of servers or compute nodes. The datacenter 504 may adhere to a networking topology (e.g., a hierarchal networking topology), such as a fat tree topology, a Slim Fly topology, a Dragonfly topology, and/or the like. The datacenter 504 routes traffic amongst the network switches and servers therein, and at least one layer of the topology in the datacenter 504 is coupled to the communication network 508 to allow networking traffic to flow between the datacenter 504 and the network device(s) 512.

Examples of the communication network 508 that may be used to connect the datacenter 504 and the network device(s) 512 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 512 may include switch, router, or Network Interface Controller (NIC), interconnect using ports, one or more of Personal Computer (PC), a laptop, a tablet, a smartphone, a server, a collection of servers, and/or any suitable computing device for sending and receiving signals over the communication network 508. In at least one example embodiment, the one or more network devices 512 correspond to another datacenter, similar to or the same as datacenter 504.

As noted above, the datacenter 504 and/or the network device(s) 512 may include storage devices and/or processing circuitry for carrying out computing tasks, for example, tasks associated with controlling the flow of data internally and/or over the communication network 508. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Additionally or alternatively, the processing circuitry may comprise hardware, such as an application specific integrated circuit (ASIC). For example, the processor may be or include one or more of an Integrated Circuit (IC) chip, a microprocessor, a CPU, a GPU, a DPU, a QPU, PPUs, a Field Programmable Gate Array (FPGA), a network interface controller (NIC), an ASIC, combinations thereof, and the like. The processing circuitry may comprise an ASIC and/or may be capable of performing as a CPU, a GPU, a network interface controller (NIC), a data processing unit (DPU), or any other computing device in which with data is received and/or transmitted. QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 504 and network device(s) 512 may include one or more communication interfaces for facilitating wired and/or wireless communication between one another and other unillustrated elements of the system 500.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links or optical interconnects using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

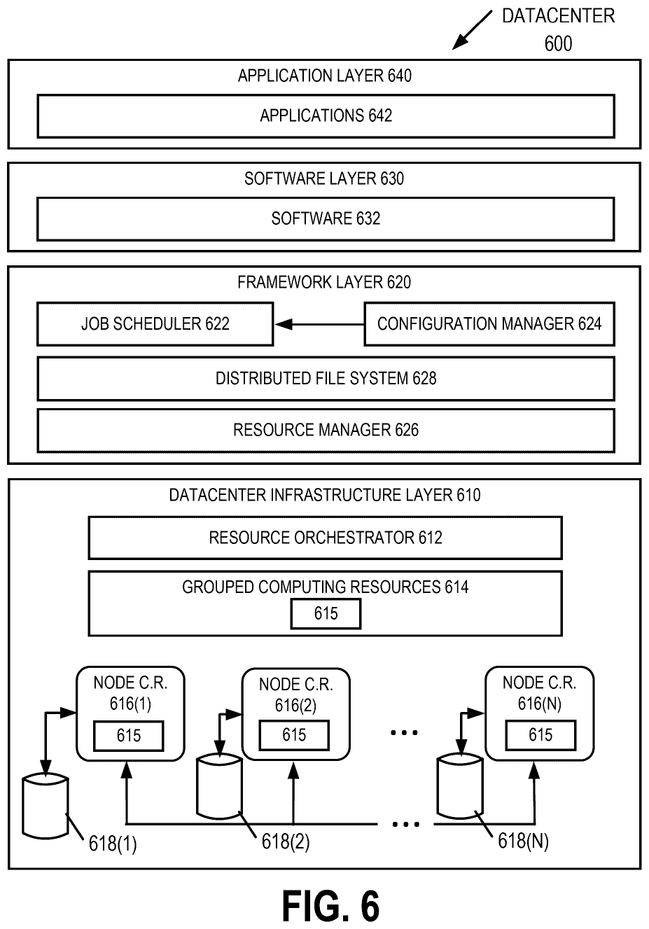

FIG. 6 provides an example datacenter 600, in which at least one embodiment may be used. In at least one embodiment, datacenter 600 includes a datacenter infrastructure layer 611, a framework layer 620, a software layer 630, and an application layer 640.

In at least one embodiment, as shown in FIG. 6, datacenter infrastructure layer 611 may include a resource orchestrator 612, grouped computing resources 614, and node computing resources (“node C.R.s”) 616(1)-616(N), where “N” represents a positive integer (which may be a different integer “N” than used in other figures). In at least one embodiment, node C.R.s 616(1)-616(N) may include, but are not limited to, any number of central processing units (“CPUs”) or other processors (including accelerators, field programmable gate arrays (FPGAs), graphics processors, etc.), memory storage devices 618(1)-618(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 616(1)-616(N) may be a server comprising one or more of above-mentioned computing resources.

In at least one embodiment, grouped computing resources 614 may include separate groupings of node C.R.s housed within one or more racks (not shown), or many racks housed in datacenters at various geographical locations (also not shown). In at least one embodiment, separate groupings of node C.R.s within grouped computing resources 614 may include grouped compute, network, memory, or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 612 may configure or otherwise control one or more node C.R.s 616(1)-616(N) and/or grouped computing resources 614. In at least one embodiment, resource orchestrator 612 may include a software design infrastructure (“SDI”) management entity for datacenter 600. In at least one embodiment, resource orchestrator 612 may include hardware, software or some combination thereof.

In at least one embodiment, as shown in FIG. 6, framework layer 620 includes a job scheduler 622, a configuration manager 624, a resource manager 626 and a distributed file system 628. In at least one embodiment, framework layer 620 may include a framework to support software 632 of software layer 630 and/or one or more application(s) 642 of application layer 640. In at least one embodiment, software 632 or application(s) 642 may respectively include web-based service software or applications, such as those provided by Amazon Web Services, Google Cloud and Microsoft Azure. In at least one embodiment, framework layer 620 may be, but is not limited to, a type of free and open-source software web application framework such as Apache Spark™ (hereinafter “Spark”) that may utilize distributed file system 628 for large-scale data processing (e.g., “big data”). In at least one embodiment, job scheduler 622 may include a Spark driver to facilitate scheduling of workloads supported by various layers of datacenter 600. In at least one embodiment, configuration manager 624 may be capable of configuring different layers such as software layer 630 and framework layer 620 including Spark and distributed file system 628 for supporting large-scale data processing. In at least one embodiment, resource manager 626 may be capable of managing clustered or grouped computing resources mapped to or allocated for support of distributed file system 628 and job scheduler 622. In at least one embodiment, clustered or grouped computing resources may include grouped computing resources 614 at datacenter infrastructure layer 611. In at least one embodiment, resource manager 626 may coordinate with resource orchestrator 612 to manage these mapped or allocated computing resources.

In at least one embodiment, software 632 included in software layer 630 may include software used by at least portions of node C.R.s 616(1)-616(N), grouped computing resources 614, and/or distributed file system 628 of framework layer 620. In at least one embodiment, one or more types of software may include, but are not limited to, Internet web page search software, e-mail virus scan software, database software, and streaming video content software.

In at least one embodiment, application(s) 642 included in application layer 640 may include one or more types of applications used by at least portions of node C.R.s 616(1)-616(N), grouped computing resources 614, and/or distributed file system 628 of framework layer 620. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 624, resource manager 626, and resource orchestrator 612 may implement any number and type of self-modifying actions based on any amount and type of data acquired in any technically feasible fashion. In at least one embodiment, self-modifying actions may relieve a datacenter operator of datacenter 600 from making possibly bad configuration decisions and possibly avoiding underutilized and/or poor performing portions of a datacenter.

In at least one embodiment, datacenter 600 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 600. In at least one embodiment, trained machine learning models corresponding to one or more neural networks may be used to infer or predict information using resources described above with respect to datacenter 600 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 615 are used to perform inferencing and/or training operations associated with one or more embodiments. In at least one embodiment, inference and/or training logic 615 may be used in system FIG. 6 for inferencing or predicting operations based, at least in part, on weight parameters calculated using neural network training operations, neural network functions and/or architectures, or neural network use cases described herein.

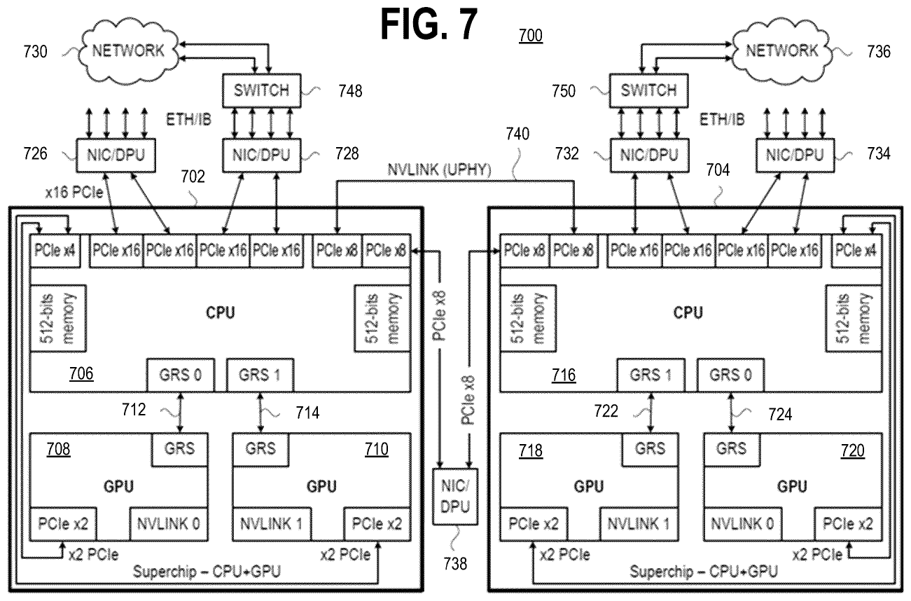

FIG. 7 is a block diagram that schematically illustrates a computing system 700, e.g., a data center or a High-Performance Computing (HPC) cluster, in accordance with an embodiment that is described herein. Computing system 700 comprises a plurality of subsystems, e.g. multiple processing devices coupled to each other, multiple network devices, and multiple networks, according to at least one embodiment. Computing system 700 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 700 and to one or more external networks 730, 736. In the present example, computing system 700 comprises a packet switch 748 that connects NIC/DPU 728 to network 730, and a packet switch 750 that connects NIC/DPU 732 to network 736.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 700 can include one or more CPUs and one or more GPUs.

FIG. 7 also demonstrates an example architecture of a multi-GPU architecture. As illustrated in the figure, computing system 700 includes a processing device 702 with a multi-GPU architecture. In particular, processing device 702 may be a system-on-chip and includes multiple subsystems such as a CPU 706, a GPU 708, and a GPU 710. CPU 706 can be coupled to GPU 708 via a die-to-die (D2D) or chip-to-chip (C2C) interconnect 712, such as a Ground-Referenced Signaling interconnect (GRS interconnect). CPU 706 can be coupled to GPU 710 via a D2D or C2C interconnect 714. CPU 706 can also couple to GPU 708 and GPU 710 via PCIe interconnects.

CPU 706 can be coupled to one or more NICs or DPUs, which are coupled to one or more networks. For example, as illustrated in FIG. 7, CPU 706 is coupled to a first NIC/DPU 726, which is coupled to a network 730. CPU 706 is also coupled to a second NIC/DPU 728, which is coupled to network 730 via switch 748. NIC/DPU 726 and NIC/DPU 728 can be coupled to network 730 over Ethernet (ETH), NVLINK or InfiniBand (IB) connections, for example.

Computing system 700 also includes a processing device 704 with a multi-GPU architecture. In particular, processing device 704 includes multiple subsystems including a CPU 716, a GPU 718, and a GPU 720. CPU 716 can be coupled to GPU 718 via an D2D or C2C interconnect 722. CPU 716 can be coupled to GPU 720 via a D2D or C2C interconnect 724. CPU 716 can also couple to GPU 718 and GPU 720 via PCIe interconnects. CPU 716 can be coupled to one or more NICs or DPUs, which are coupled to one or more networks. For example, as illustrated in FIG. 7, CPU 716 is coupled to a first NIC/DPU 732, which is coupled to a network 736. CPU 716 is also coupled to a second NIC/DPU 734, which is coupled to network 736 via switch 750. NIC/DPU 732 and NIC/DPU 734 can be coupled to network 736 over Ethernet (ETH), NVLINK or InfiniBand (IB) connections.

In at least one embodiment, processing device 702 and processing device 704 can communication with each other via a NIC/DPU 738, such as over PCIe interconnects. Processing device 702 and processing device 704 can also communicate with each other over a high-bandwidth communication interconnects 740, such as an NVLink interconnect or other high-speed interconnects. The packet switches in FIG. 7 may comprise, for example, Nvidia Quantum-2 switches. The NICs/DPUs in the figure may comprise, for example, Nvidia Bluefield DPUs.

In various embodiments, one or more of the interconnects 712, 714, 722, 724 may be optical interconnects disclosed herein. Additionally, in various embodiments, switches 748, 750 may be in communication with NIC/DPU 728, 732, respectively, via one or more optical interconnects disclosed herein. In some embodiments, NIC/DPU 726, 734 may be in communication with one or more additional elements via optical interconnects disclosed herein. For example, various elements of the computing system 700 may be in communication with one another via one or more optical interconnects disclosed herein.

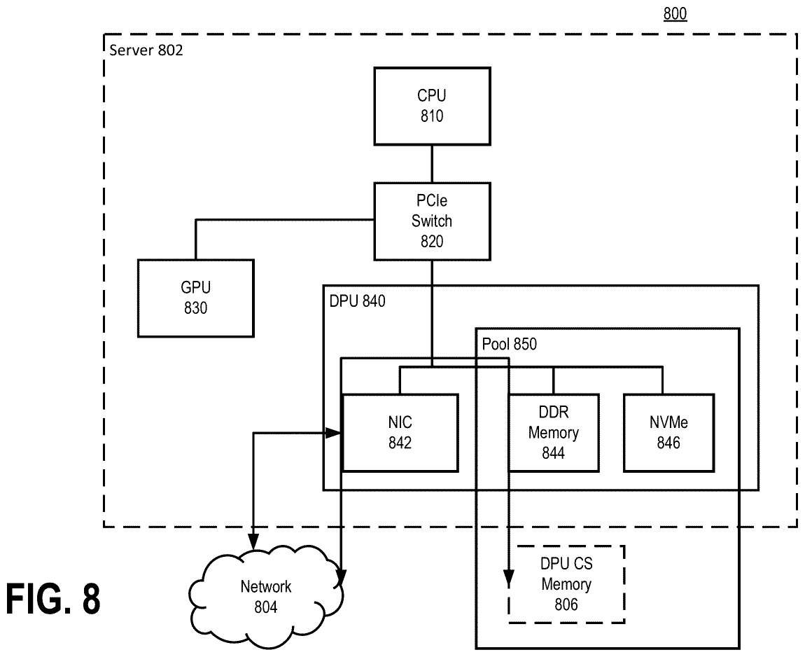

FIG. 8 illustrates an example computing environment 800 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 800 may include a server 802 which may be used to perform high performance computing (HPC) workloads, such as AI training or machine learning model training. In an embodiment, the server 802 may be an application instance or a compute node. The server 802 may include a CPU 810 associated with a switch 820, such as a peripheral component interconnect express (PCIe) switch, which may control at least some data transmission over communication paths interconnecting various components. In an embodiment, the CPU 810 may include a root complex processor.

The PCIe switch 820 may also be associated with a GPU 830 and a DPU 840, and may transmit data between at least some of the CPU 810, the GPU 830, the DPU 840, and other components (e.g., via one or more optical interconnects disclosed herein). In an embodiment, the PCIe switch 820 may be associated with more than one GPU or more than one DPU. In another embodiment, the PCIe switch 820 may be located within the DPU 840. The PCIe switch 820 may manage the transfer of at least some data between the CPU 810, the GPU 830, and the DPU 840. In another embodiment, the number of GPUs associated with the PCIe switch 820 may be equal to the number of DPUs associated with the PCIe switch 820. In at least one embodiment, the server 802 may include, without limitation, any number of the CPUs 810, the PCIe switches 820, the GPUs 830, and/or the DPUs 840, in any combination. For example, in at least one embodiment, server 802 could include eight, sixteen, thirty-two, and/or more GPUs 830. In at least one embodiment, communication paths interconnecting various components, including but not limited to the CPU 810, the PCIe switch 820, the GPU 830, and the DPU 840, in FIG. 8 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 840 may include a network interface controller (NIC) 842, a DDR memory 844, and a non-volatile memory express (NVMe) device 846. The NIC 842 may be able to interface with a network 804, which may also interface with additional NVMe devices available to the DPU 840, such as over fabric. In an embodiment, the DPU 840 may not include the NVMe device 846. In another embodiment, the NVMe device 846 may be located on the server 802 and not on the DPU 840. In yet another embodiment, the computing environment 800 may include more than one of the NVMe device 846, such as a first NVMe device in the DPU 840 and a second first NVMe device on the server 802 an associated directly with the PCIe switch 820. In an embodiment, the DPU 840 may not include the DDR memory 844 and may include a computational storage services (CSS) in place of, or in addition to, the DDR memory 844. For example, computing environment 800 may include DPU computational storage (CS) memory 806 available to the DPU 840 as part of the CSS. The network 804 may be able to interface with the DPU CS memory 806 through the NIC 842, according to any suitable interface protocol, such as remote direct memory access (RDMA) over Ethernet, InfiniBand, Fiber Channel, etc.

The total memory of the computing environment 800 available for data storage may be expanded through the use of the DPU 840 on nodes of the system. The DPU 840 may have access to a pool 850 of memory already available to the server 802, such as double data rate (DDR) memory, on-board NVMe devices, NVMe devices over fabric, and CS. The pool 850 of memory may include at least one of the DDR memory 844, NVMe 846, and the DPU CS memory 806. The DPU 840 may also be able to access the available memory of other DPUs as part of the pool 850, and other DPUs may be able to access the available memory of DPU 840, such as the pool 850. This available memory can be accessed and utilized for data storage, without the addition of compute resources, such as compute nodes, which would be required using other solutions. The available pool 850 accessible to the DPU 840 may be provisioned for the server 802 to expand the total memory available for data storage, such as to reduce the data storage load on the CPU 810 or the GPU 830, which can instead increase the utilization of their memory for processing. For example, during training of an AI, the model states, residual states, activation functions, and checkpoints can be stored, or offloaded, on the pool 850 accessible to the DPU 840.

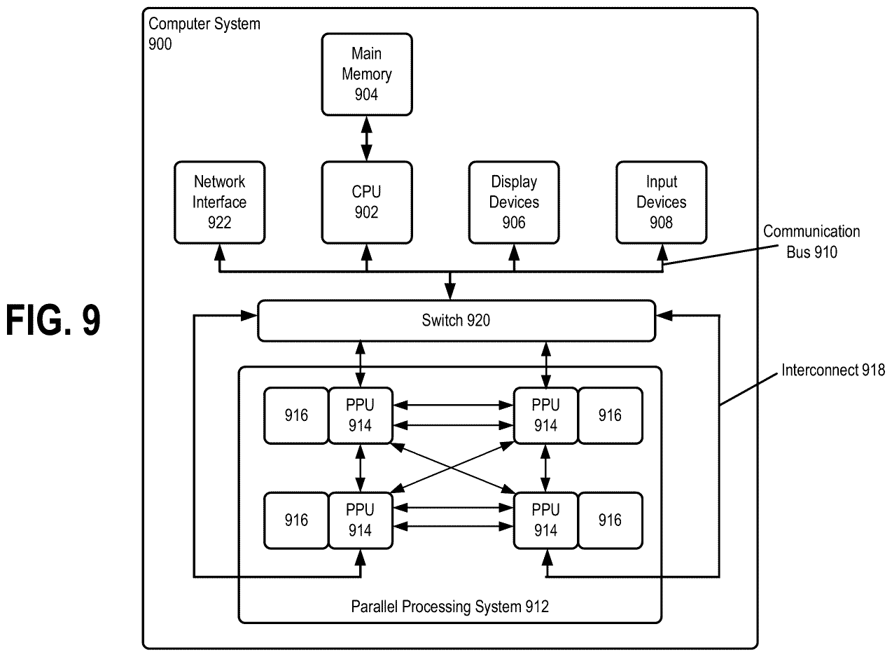

FIG. 9 illustrates a computer system 900, according to at least one embodiment. In at least one embodiment, computer system 900 comprises at least one optical interconnect of an example embodiment.

In at least one embodiment, computer system 900 comprises, without limitation, at least one central processing unit (“CPU”) 902 that is connected to a communication bus 910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 900 includes, without limitation, a main memory 904 and control logic (e.g., implemented as hardware, software, or a combination thereof) and data are stored in main memory 904 which may take form of random access memory (“RAM”). In at least one embodiment, a network interface subsystem (“network interface”) 922 provides an interface to other computing devices and networks for receiving data from and transmitting data to other systems from computer system 900.

In at least one embodiment, computer system 900, in at least one embodiment, includes, without limitation, input devices 908, parallel processing system 912, and display devices 906 which can be implemented using a conventional cathode ray tube (“CRT”), liquid crystal display (“LCD”), light emitting diode (“LED”), plasma display, or other suitable display technologies. In at least one embodiment, user input is received from input devices 908 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 904 and/or secondary storage. Computer programs, if executed by one or more processors, enable computer system 900 to perform various functions in accordance with at least one embodiment. memory 904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 902; parallel processing system 912; an integrated circuit capable of at least a portion of capabilities of both CPU 902; parallel processing system 912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 900 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 912 includes, without limitation, a plurality of parallel processing units (“PPUs”) 914 and associated memories 916. In at least one embodiment, PPUs 914 are connected to a host processor or other peripheral devices via an interconnect 918 and a switch 920 or multiplexer. In at least one embodiment, parallel processing system 912 distributes computational tasks across PPUs 914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 914, although such shared memory may incur performance penalties relative to use of local memory and registers resident to a PPU 914. In at least one embodiment, operation of PPUs 914 is synchronized through use of a command such as syncthreads( ), wherein all threads in a block (e.g., executed across multiple PPUs 914) to reach a certain point of execution of code before proceeding.

The PPUs 914 may be in communication with one another and/or switch 1420 via one or more optical interconnects in accordance with example embodiments disclosed herein.

### Tray Eject Detection Method

Having described example systems in accordance with the present disclosure, example processes of the present disclosure will now be discussed. It will be appreciated that each of the flowcharts depicts an example computer-implemented process that is performable by one or more apparatuses, systems, circuits, devices, and/or computer program products described herein, for example utilizing one or more of the specially configured components thereof.

Although the example processes depict a particular sequence of operations, the sequence may be altered without departing from the scope of the present disclosure. For example, some of the operations depicted may be performed in parallel or in a different sequence that does not materially affect the function of the processes.

The blocks indicate operations of each process. Such operations may be performed in any of a number of ways, including, without limitation, in the order and manner as depicted and described herein. In some embodiments, one or more blocks of any of the processes described herein occur in-between one or more blocks of another process, before one or more blocks of another process, in parallel with one or more blocks of another process, and/or as a sub-process of a second process. Additionally or alternatively, any of the processes in various embodiments include some or all operational steps described and/or depicted, including one or more optional blocks in some embodiments. With regard to the flowcharts illustrated herein, one or more of the depicted block(s) in some embodiments is/are optional in some, or all, embodiments of the disclosure. Optional blocks are depicted with broken (or “dashed”) lines. Similarly, it should be appreciated that one or more of the operations of each flowchart may be combinable, replaceable, and/or otherwise altered as described herein.

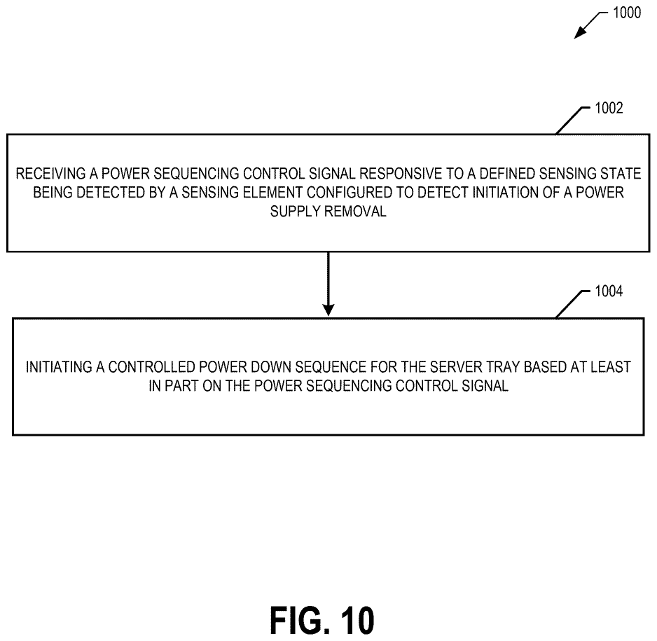

FIG. 10 illustrates a process 1000 depicting example operations for tray eject detection in accordance with one or more embodiments of the present disclosure. The process may embody an example computer-implemented method. In some embodiments, the process 1000 is embodied by computer program code stored on a non-transitory computer-readable storage medium of a computer program product configured for execution to perform the process as depicted and described. Alternatively or additionally, in some embodiments, the process is performed by one or more specially configured computing devices, such as the controller circuit 106 alone or in communication with one or more other component(s), device(s), system(s), and/or the like. In this regard, in some embodiments, the controller circuit 106 is specially configured by computer-coded instructions (e.g., computer program instructions) stored thereon, for example in memory and/or another component depicted and/or described herein and/or otherwise accessible to the controller circuit 106, for performing the operations as depicted and described. In some embodiments, the controller circuit 106 is in communication with one or more external apparatus(es), system(s), device(s), and/or the like, to perform one or more of the operations as depicted and described. For example, the controller circuit 106 in some embodiments is in communication with and/or incorporated as part of the server tray 102. For purposes of simplifying the description, the processes 1100 is described as performed by and from the perspective of the controller circuit 106.

In some embodiments, the process 1000 includes receiving a power sequencing control signal responsive to a defined eject state being detected by a sensing element configured to detect initiation of a power supply removal, as shown at block 1002.

In some embodiments, the process 1000 includes initiating a controlled power down sequence for the server tray based at least in part on the power sequencing control signal, as shown at block 1004.

Although an example processing system has been described above, implementations of the subject matter and the functional operations described herein may be implemented in other types of digital electronic circuitry, or in computer software, firmware, or hardware, including the structures disclosed in this specification and their structural equivalents, or in combinations of one or more of them.

Embodiments of the subject matter and the operations described herein may be implemented in digital electronic circuitry, or in computer software, firmware, or hardware, including the structures disclosed in this specification and their structural equivalents, or in combinations of one or more of them. Embodiments of the subject matter described herein may be implemented as one or more computer programs, i.e., one or more modules of computer program instructions, encoded on computer storage medium for execution by, or to control the operation of, information/data processing apparatus. Alternatively, or in addition, the program instructions may be encoded on an artificially generated propagated signal, e.g., a machine-generated electrical, optical, or electromagnetic signal, which is generated to encode information/data for transmission to suitable receiver apparatus for execution by an information/data processing apparatus. A computer storage medium may be, or be included in, a computer-readable storage device, a computer-readable storage substrate, a random or serial access memory array or device, or a combination of one or more of them. Moreover, while a computer storage medium is not a propagated signal, a computer storage medium may be a source or destination of computer program instructions encoded in an artificially generated propagated signal. The computer storage medium may also be, or be included in, one or more separate physical components or media (e.g., multiple CDs, disks, or other storage devices).

The operations described herein may be implemented as operations performed by an information/data processing apparatus on information/data stored on one or more computer-readable storage devices or received from other sources.

The term “apparatus” encompasses all kinds of apparatus, devices, and machines for processing data, including by way of example a programmable processor, a computer, a system on a chip, or multiple ones, or combinations, of the foregoing. The apparatus may include special purpose logic circuitry, e.g., an FPGA (field programmable gate array) or an ASIC (application-specific integrated circuit). The apparatus may also include, in addition to hardware, code that creates an execution environment for the computer program in question, e.g., code that constitutes processor firmware, a protocol stack, a repository management system, an operating system, a cross-platform runtime environment, a virtual machine, or a combination of one or more of them. The apparatus and execution environment may realize various different computing model infrastructures, such as web services, distributed computing and grid computing infrastructures.

A computer program (also known as a program, software, software application, script, or code) may be written in any form of programming language, including compiled or interpreted languages, declarative or procedural languages, and it may be deployed in any form, including as a stand-alone program or as a module, component, subroutine, object, or other unit suitable for use in a computing environment. A computer program may, but need not, correspond to a file in a file system. A program may be stored in a portion of a file that holds other programs or information/data (e.g., one or more scripts stored in a markup language document), in a single file dedicated to the program in question, or in multiple coordinated files (e.g., files that store one or more modules, sub-programs, or portions of code). A computer program may be deployed to be executed on one computer or on multiple computers that are located at one site or distributed across multiple sites and interconnected by a communication network.

The processes and logic flows described herein may be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto-optical disks, or optical disks. However, a computer need not have such devices. Devices suitable for storing computer program instructions and information/data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory may be supplemented by, or incorporated in, special purpose logic circuitry.

To provide for interaction with a user, embodiments of the subject matter described herein may be implemented on a computer comprising a display device, e.g., a CRT (cathode ray tube) or LCD (liquid crystal display) monitor, for displaying information/data to the user and a keyboard and a pointing device, e.g., a mouse or a trackball, by which the user may provide input to the computer. Other kinds of devices may be used to provide for interaction with a user as well; for example, feedback provided to the user may be any form of sensory feedback, e.g., visual feedback, auditory feedback, or tactile feedback; and input from the user may be received in any form, including acoustic, speech, or tactile input. In addition, a computer may interact with a user by sending documents to and receiving documents from a device that is used by the user; for example, by sending web pages to a web browser on a user's client device in response to requests received from the web browser.

Embodiments of the subject matter described herein may be implemented in a computing system that includes a back-end component, e.g., as an information/data server, or that includes a middleware component, e.g., an application server, or that includes a front-end component, e.g., a client computer comprising a graphical user interface or a web browser through which a user may interact with an implementation of the subject matter described herein, or any combination of one or more such back-end, middleware, or front-end components. The components of the system may be interconnected by any form or medium of digital information/data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system may include clients and servers. A client and server are generally remote from each other and typically interact through a communication network. The relationship of client and server arises by virtue of computer programs running on the respective computers and comprising a client-server relationship to each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) may be received from the client device at the server.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products.

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

1. A server tray comprising:
a sensing element configured to detect initiation of a power supply removal; and
a controller circuit configured to initiate a controlled power down sequence for the server tray responsive to a defined eject state being detected by the sensing element.

2. The server tray of claim 1, wherein the sensing element is located at a tray handle of the server tray.

3. The server tray of claim 2, wherein the sensing element is a pressure switch configured to contact a portion of the tray handle when a power supply of a server rack is attached to the server tray.

4. The server tray of claim 2, wherein the sensing element is a rotary switch configured to detect a position of the tray handle.

5. The server tray of claim 2, wherein the sensing element is an accelerometer configured to detect movement of the tray handle.

6. The server tray of claim 2, wherein the sensing element is a light detector configured to detect light when the tray handle satisfies the defined eject state.

7. The server tray of claim 2, wherein the sensing element is a capacitor-based sensing element configured to detect a change in stored electrical charge in response to the defined eject state being satisfied.

8. The server tray of claim 1, wherein the sensing element is a first sensing element located at a first tray handle of the server tray, and wherein the server tray further comprises:
a second sensing element located at a second tray handle of the server tray and configured to detect initiation of the power supply removal.

9. The server tray of claim 8, wherein the controller circuit is configured to initiate the controlled power down sequence for the server tray responsive to the defined eject state being detected by the second sensing element.

10. The server tray of claim 1, wherein the controller circuit is configured to provide the controlled power down sequence for a defined interval of time to maintain power for the server tray for the defined interval of time.

11. The server tray of claim 1, further comprising:
one or more processing modules communicatively coupled to the controller circuit,
wherein the controller circuit is configured to provide the controlled power down sequence for a defined interval of time to initiate a power-down sequence for the one or more processing modules during the defined interval of time.

12. A processing system comprising:
a server rack;
one or more server trays supported within the server rack, wherein at least one server tray of the one or more server trays comprises:
a sensing element configured to detect initiation of a power supply removal; and
a controller circuit configured to initiate a controlled power down sequence for the at least one server tray responsive to a defined eject state being detected by the sensing element.

13. The processing system of claim 12, wherein the sensing element is located at a tray handle of the at least one server tray.

14. The processing system of claim 13, wherein the sensing element is a pressure switch configured to contact a portion of the tray handle when a power supply of the server rack is attached to the at least one server tray.

15. The processing system of claim 13, wherein the sensing element is a rotary switch configured to detect a position of the tray handle.

16. The processing system of claim 13, wherein the sensing element is an accelerometer configured to detect movement of the tray handle.

17. The processing system of claim 13, wherein the sensing element is a light detector configured to detect light when the tray handle satisfies the defined eject state.

18. The processing system of claim 13, wherein the sensing element is a capacitor-based sensing element configured to detect a change in stored electrical charge in response to the defined eject state being satisfied.

19. The processing system of claim 11, wherein the controller circuit is configured to provide the controlled power down sequence for a defined interval of time to maintain power for the at least one server tray for the defined interval of time.

20. A method comprising:
receiving a power sequencing control signal responsive to a defined eject state being detected by a sensing element configured to detect initiation of a power supply removal; and
initiating a controlled power down sequence for the server tray based at least in part on the power sequencing control signal.
